(19) United States
(12) Patent Application Publication
(10) Pub. No.: US 2023/0387883 A1
(43) Pub. Date: Nov. 30, 2023

(54) RESONATOR AND METHOD OF PREPARING A RESONATOR

(71) Applicant: Wuhan MEMSonics Technologies Co., Ltd., Wuhan (CN)

(72) Inventors: Chao GAO, Wuhan (CN); Yang ZOU, Wuhan (CN); Yao CAI, Wuhan (CN); Dawdon CHEAM, Singapore (SG); Yuanhang QU, Wuhan (CN); Yaxin WANG, Wuhan (CN); Bowoon SOON, Singapore (SG); Chengliang SUN, Wuhan (CN)

(21) Appl. No.: 18/201,180

(22) Filed: May 24, 2023

(30) Foreign Application Priority Data
May 26, 2022 (CN) 202210591204.1

(51) Int. Cl. H03H 9/17; H03H 9/02; H03H 9/13; H03H 3/02

(52) U.S. Cl. CPC H03H 9/173; H03H 9/02047; H03H 9/02157; H03H 9/13; H03H 3/02; H03H 2003/021

(57) ABSTRACT

The present application provides a resonator and a method of preparing same, and relates to the field of semiconductor technologies. The method includes: providing a device wafer, wherein the device wafer includes a first substrate and a piezoelectric layer, a bottom electrode, and a first mass loading layer formed in sequence on the first substrate; forming, on the bottom electrode, a sacrificial layer covering the first mass loading layer; forming a supporting layer on one side of the device wafer with the sacrificial layer; forming a second substrate on the supporting layer through a bonding process; removing the first substrate to expose the piezoelectric layer; forming a top electrode and a second mass loading layer in sequence on the piezoelectric layer; and releasing the sacrificial layer to form a cavity between the first mass loading layer and the supporting layer. Therefore, the resonator is correspondingly tuned by controlling a ratio of an area of the first mass loading layer in an effective working region of the resonator to an area of the second mass loading layer in the effective working region of the resonator, thereby manufacturing resonators with different resonant frequencies, effectively avoiding loss caused by tuning with an external element, and ensuring good performance of the resonator.

### CROSS-REFERENCE TO RELATED APPLICATION

This present disclosure claims the priority to Chinese patent application No. 202210591204.1, entitled “Resonator and method of preparing a resonator”, and filed on May 26, 2022 in China, and the contents of which are hereby incorporated by reference in its entirety.

### TECHNICAL FIELD

The present application relates to the technical field of semiconductors, and specifically relates to a resonator and a method of preparing a resonator.

### BACKGROUND

With the advent of 5G era, mobile communication systems are being developed towards higher frequencies and wider bands. A radio frequency filter in communication equipment is the foundation of receiving and transmitting signals. A filter in a radio frequency front-end serves as a core device, so that the performance of the filter directly determines the quality of a radio frequency front-end module. The filter is composed of several resonators. Therefore, the performance of the resonators also directly determines the quality of the filter. A film bulk acoustic resonator is widely used as a type of resonator.

A resonant frequency of the film bulk acoustic resonator is determined by a thickness of this filter, which makes it impossible to manufacture multiple resonators operating at different frequencies on one wafer. A frequency modulation technology of the existing film bulk acoustic resonator mainly involves electric tuning, which adjusts the frequency of the film bulk acoustic resonator through an external element. However, tuning through an external element can cause significant loss, resulting in a significant decrease in the performance of the film bulk acoustic resonator.

### SUMMARY

The present application aims to provide a resonator and a method of preparing a resonator to solve the shortcomings in the prior art, so as to solve the problem of a decrease in the performance caused by introduction of an external element to achieve tuning of an existing film bulk acoustic resonator.

In order to achieve the above objective, the technical solution of the embodiments of the present application is as follows:

According to one aspect of the embodiments of the present application, a method of preparing a resonator is provided. The method includes: providing a device wafer, wherein the device wafer includes a first substrate and a piezoelectric layer, a bottom electrode, and a first mass loading layer formed in sequence on the first substrate, and the device wafer further includes a sacrificial layer formed on the bottom layer and covering the first mass loading layer; forming a supporting layer on one side of the device wafer with the sacrificial layer; forming a second substrate on the supporting layer through a bonding process; removing the first substrate to expose the piezoelectric layer; forming a top electrode and a second mass loading layer in sequence on the piezoelectric layer; and releasing the sacrificial layer to form a cavity between the first mass loading layer and the supporting layer, wherein the first mass loading layer, the second mass loading layer, and the cavity are all located in an effective working region of the resonator.

Optionally, the first mass loading layer comprise a plurality of mass blocks distributed on a same layer, and/or the second mass loading layer comprise a plurality of mass blocks distributed on a same layer.

Optionally, the forming a second substrate on the supporting layer through a bonding process includes: forming a first transition layer on the supporting layer; forming a second transition layer on the second substrate; and bonding the first transition layer with the second transition layer to form the second substrate on the supporting layer.

Optionally, the first transition layer includes a first buffer layer formed on the supporting layer and a first bonding layer formed on the first buffer layer; and the second transition layer includes a second buffer layer formed on the second substrate and a second bonding layer formed on the second buffer layer.

Optionally, the first transition layer includes a first buffer layer formed on the supporting layer; and the second transition layer includes a second buffer layer formed on the second substrate.

Optionally, after forming a first buffer layer on the supporting layer, the method further includes: flattening the first buffer layer.

Optionally, the releasing the sacrificial layer to form a cavity between the first mass loading layer and the supporting layer includes: etching one side surface of the top electrode facing away from the bottom electrode to form a through hole penetrating through the sacrificial layer; and releasing the sacrificial layer through the through hole to form the cavity between the first mass loading layer and the supporting layer.

According to another aspect of the embodiments of the present application, a resonator is provided, including a second substrate and a supporting layer arranged on the second substrate; a bottom electrode, a piezoelectric layer, and a top electrode are arranged on the supporting layer in sequence, and a cavity is formed between the bottom electrode and the supporting layer; a first mass loading layer is formed on a side surface of the bottom electrode close to the cavity, and a second mass loading layer is formed on a side surface of the top electrode facing away from the cavity; and the first mass loading layer, the second mass loading layer, and the cavity are all located in an effective working region of the resonator.

Optionally, the first mass loading layer comprise a plurality of mass blocks distributed on a same layer, and/or the second mass loading layer comprise a plurality of mass blocks distributed on a same layer.

Optionally, a first transition layer and a second transition layer bonded with each other are further arranged between the second substrate and the supporting layer.

Optionally, a plurality of first mass blocks are arranged on the first mass loading layer, and are dispersed on the bottom electrode.

Optionally, a shape of a cross section of each first mass block is a closed pattern composed of a circle, or a trapezoid, or a triangle, or an arc, and distances between centers of two adjacent first mass blocks are equal.

Optionally, a plurality of second mass blocks are arranged on the second mass loading layer, and the second mass blocks are dispersed on the top electrode.

Optionally, a shape of a cross section of each second mass block is a closed pattern composed of a circle, or a trapezoid, or a triangle, or an arc, and distances between centers of two adjacent second mass blocks are equal.

Optionally, a first total projection area of the first mass blocks in the effective working region of the resonator is obtained; a second total projection area of the second mass blocks in the effective working region of the resonator is obtained; and a frequency of the resonator is adjusted by controlling a ratio of the first total projection area to the second total projection area.

Optionally, the ratio of the first total projection area to the second total projection area is 1:1.

Optionally, the ratio of the first total projection area to the second total projection area is 1:0.

Optionally, the ratio of the first total projection area to the second total projection area is 1:0.5625.

Optionally, the ratio of the first total projection area to the second total projection area is 1:1.5.

Optionally, the cross section of the first mass block has the same shape as the shape of the cross section of the second mass block.

The present application has the following beneficial effects.

The present application provides a resonator and a method of preparing a resonator. The method includes: providing a device wafer, wherein the device wafer includes a first substrate and a piezoelectric layer, a bottom electrode, and a first mass loading layer formed in sequence on the first substrate, and the device wafer further includes a sacrificial layer formed on the bottom layer and covering the first mass loading layer; forming a supporting layer on one side of the device wafer with the sacrificial layer; forming a second substrate on the supporting layer through a bonding process; removing the first substrate to expose the piezoelectric layer; forming a top electrode and a second mass loading layer in sequence on the piezoelectric layer; and releasing the sacrificial layer to form a cavity between the first mass loading layer and the supporting layer, wherein the first mass loading layer, the second mass loading layer, and the cavity are all located in an effective working region of the resonator. the resonator is correspondingly tuned by controlling a ratio of an area of the first mass loading layer in an effective working region of the resonator to an area of the second mass loading layer in the effective working region of the resonator, so that the ratios of the areas of the mass loading layers of various resonators in the effective working regions can be controlled to be different on the same wafer, thereby manufacturing resonators with different resonant frequencies, effectively avoiding loss caused by tuning with an external element, and ensuring good performance of the resonator.

### BRIEF DESCRIPTION OF THE DRAWINGS

In order to explain the technical solutions of the embodiments of the present application more clearly, the following will briefly introduce the accompanying drawings used in the embodiments. It should be understood that the drawings in the following description only illustrate some embodiments of the present application and thus shall not be deemed as limiting the scope. Those of ordinary skill in the art can obtain other related drawings based on these drawings without creative work.

FIG. 1 is a flowchart of a method of preparing a resonator provided according to an embodiment of the present application;

FIG. 2 is a state diagram I of a method of preparing a resonator provided according to an embodiment of the present application;

FIG. 3 is a state diagram II of a method of preparing a resonator provided according to an embodiment of the present application;

FIG. 4 is a state diagram III of a method of preparing a resonator provided according to an embodiment of the present application;

FIG. 5 is a state diagram IV of a method of preparing a resonator provided according to an embodiment of the present application;

FIG. 6 is a state diagram V of a method of preparing a resonator provided according to an embodiment of the present application;

FIG. 7 is a state diagram VI of a method of preparing a resonator provided according to an embodiment of the present application;

FIG. 8 is a state diagram VII of a method of preparing a resonator provided according to an embodiment of the present application;

FIG. 9 is a state diagram VIII of a method of preparing a resonator provided according to an embodiment of the present application;

FIG. 10 is a state diagram IX of a method of preparing a resonator provided according to an embodiment of the present application;

FIG. 11 is a state diagram X of a method of preparing a resonator provided according to an embodiment of the present application;

FIG. 12 is a schematic structural diagram of a resonator provided according to an embodiment of the present application;

FIG. 13 is a top view I of a resonator provided according to an embodiment of the present application;

FIG. 14 is a state diagram I of another method of preparing a resonator provided according to an embodiment of the present application;

FIG. 15 is a state diagram II of another method of preparing a resonator provided according to an embodiment of the present application;

FIG. 16 is a schematic structural diagram of a filter provided according to an embodiment of the present application;

FIG. 17 is a top view II of a resonator provided according to an embodiment of the present application;

FIG. 18 is a top view III of a resonator provided according to an embodiment of the present application;

FIG. 19 is a top view IV of a resonator provided according to an embodiment of the present application;

FIG. 20 is a top view V of a resonator provided according to an embodiment of the present application; and

FIG. 21 is a schematic diagram of frequency changes of a resonator provided according to an embodiment of the present application.

### NUMERALS

10: first substrate; 20: piezoelectric layer; 30: bottom electrode; 40: first mass loading layer; 50: sacrificial layer; 60: supporting layer; 51: first buffer layer; 70: first bonding layer; 11: second substrate; 52: second buffer layer; 71: second bonding layer; 80: electrode outlet hole; 90: top electrode; 91: extraction electrode; 100: second mass loading layer; 110: through hole; and 120: cavity.

### DETAILED DESCRIPTION OF THE EMBODIMENTS

Implementations described below represent necessary information enabling those skilled in the art to practice the implementations, and show the best mode of practicing the implementations. After reading the following description with reference to the accompanying drawings, those skilled in the art will understand the concepts of the present disclosure and recognize the applications of these concepts not specifically proposed herein. It should be understood that these concepts and applications fall within the scope of the present disclosure and the attached claims.

It should be understood that although the terms first, second, and the like can be used to describe various elements herein, these elements should not be limited by these terms. These terms are only used to distinguish one element from another. For example, without departing from the scope of the present disclosure, a first element may be referred to as a second element, and similarly, the second element may be referred to as the first element. As used in this article, the term “and/or” includes any and all combinations of one or more of the associated listed items.

It should be understood that when one element (for example, a layer, a region, or a substrate) is referred to as being “on another element” or “extending to another element”, it can be directly on or extend to another element, or there may also be an intermediate element. On the contrary, when one element is referred to as being “directly on another element” or “directly extending to another element”, there is no intermediate element. Similarly, it should be understood that when one element (for example, a layer, a region, or a substrate) is referred to as being “on another element” or “extending on another element”, it can be directly on another element or directly extend on another element, or there may also be an intermediate element. On the contrary, when one element is referred to as being “directly on another element” or “directly extending on another element”, there is no intermediate element. It should also be understood that when one element is referred to as being “connected” or “coupled” to another element, it can be directly connected or coupled to another element, or there may be an intermediate element. On the contrary, when one element is referred to as being “directly connected” or “directly coupled” to another element, there is no intermediate element.

The terms such as “below” or “above” or “upper” or “lower” or “horizontal” or “vertical” can be used herein to describe a relationship between an element, layer, or region and another element, layer, or region, as shown in the figures. It should be understood that these terms and those discussed earlier are intended to cover different orientations of a device other than those depicted in the figures.

The terms used herein are only for the purpose of describing specific implementations and are not intended to limit the present disclosure. As used herein, unless explicitly stated above and below, the singular forms “a/an”, “one”, and “said” are intended to also include a plural form. It should also be understood that when used herein, the term “include” indicates the presence of the features, integers, steps, operations, elements, and/or components, but does not exclude the presence or addition of one or more other features, integers, steps, operations, elements, components, and/or groups of the aforementioned items.

Unless otherwise defined, all the terms used herein (including technical and scientific terms) have the same meanings as those commonly understood by those of ordinary skill in the art. It should also be understood that the terms used herein should be interpreted as having meanings consistent with their meanings in this specification and related fields, and cannot be interpreted in an idealized or overly formal sense, unless explicitly defined herein.

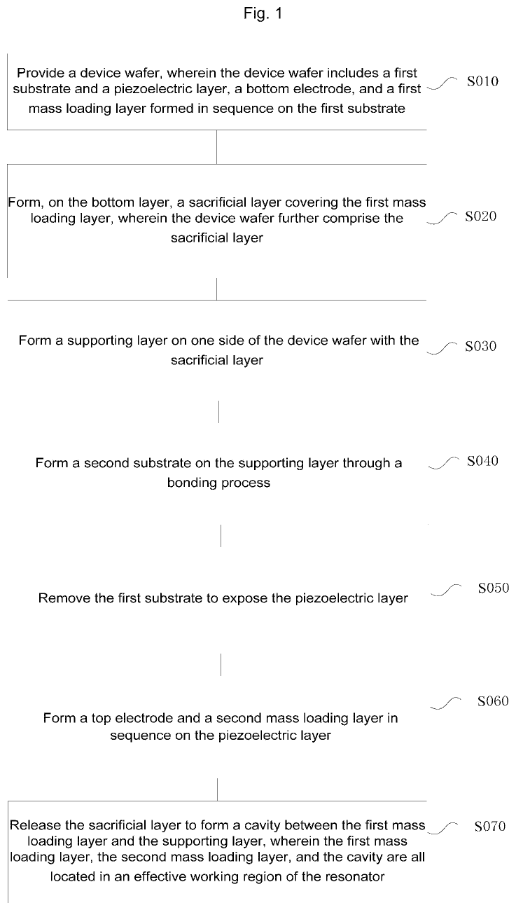

According to one aspect of the embodiments of the present application, a method of preparing a resonator is provided. As shown in FIG. 1, the method includes:
S010: Provide a device wafer, wherein the device wafer includes a first substrate and a piezoelectric layer, a bottom electrode, and a first mass loading layer formed in sequence on the first substrate.
S020: Form, on the bottom layer, a sacrificial layer covering the first mass loading layer, wherein the device wafer further comprise the sacrificial layer.
S030: Form a supporting layer on one side of the device wafer with the sacrificial layer.
S040: Form a second substrate on the supporting layer through a bonding process.
S050: Remove the first substrate to expose the piezoelectric layer.
S060: Form a top electrode and a second mass loading layer in sequence on the piezoelectric layer.
S070: Release the sacrificial layer to form a cavity between the first mass loading layer and the supporting layer, wherein the first mass loading layer, the second mass loading layer, and the cavity are all located in an effective working region of the resonator.

In order to avoid loss caused by turning the resonator by an external element, in this application, the first mass loading layer is manufactured on a surface of the bottom electrode facing away from the piezoelectric layer, and the second mass loading layer is manufactured on a surface of the top electrode away from the piezoelectric layer. The resonator is correspondingly tuned by controlling a ratio of an area of the first mass loading layer in an effective working region of the resonator to an area of the second mass loading layer in the effective working region of the resonator. On the one hand, the ratios of the areas of the mass loading layers of various resonators in the effective working regions can be controlled to be different on the same wafer, thereby manufacturing resonators with different resonant frequencies, effectively avoiding the loss caused by tuning with the external element, and ensuring good performance of the resonator. On the other hand, integrating the process of manufacturing the first mass loading layer and the second mass loading layer with the process of preparing a resonator achieves preparation of a resonator with mass loading layers. On the other hand, the mass loading layers are distributed on both the top electrode and the bottom electrode for tuning, which can further expand a tunable frequency range of the resonator. Still on the other hand, by combining the bonding process with a substrate transferring manner, it is more convenient to manufacture the mass loading layers on both the top electrode and the bottom electrode. Thicknesses of the various layers of the resonator remain unchanged, an area of the first mass loading layer in the effective region of the resonator is controlled to remain unchanged, and an area of the second mass loading layer in the effective region of the resonator is changed, thereby changing a ratio of the areas of the first mass loading layer and the second mass loading layer to the effective region of the resonator. That is, the resonator is turned by controlling the ratio of the areas of the two mass loading layers. The manner of controlling the areas of the mass loading layers by a mask and photolithography is achieved by designing an area of a mask plate in advance, that is, the area of the mask plate is an area of a corresponding mass loading layer after the photolithography.

To further describe the method of preparing the resonator in the present application, the following will be explained in the form of embodiments in conjunction with the accompanying drawings.

In one implementation:

Referring to FIG. 3, a device wafer is provided. The device wafer includes a first substrate 10, a piezoelectric layer 20, a bottom electrode 30, and a first mass loading layer 40. The first substrate may be a Si substrate, a sapphire substrate, a SiC substrate, or the like. The present application does not limit the first substrate which can be reasonably selected according to an actual need.

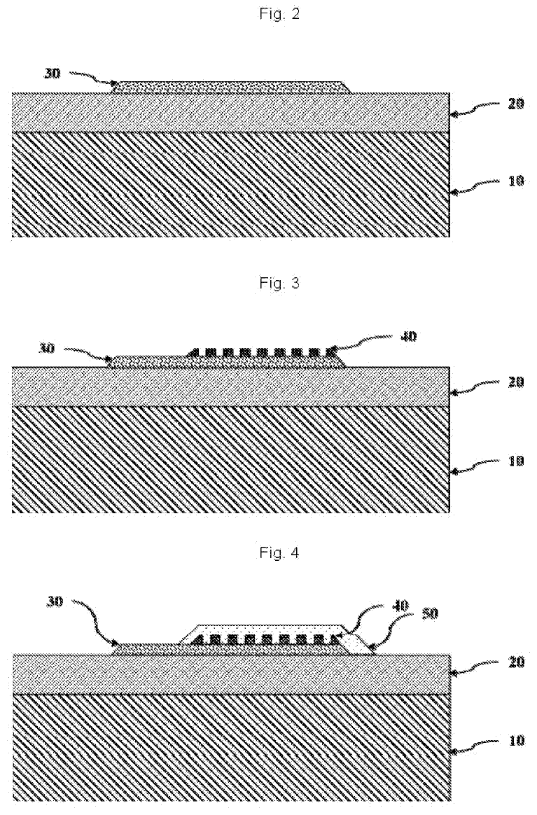

As shown in FIG. 2, a piezoelectric layer 20 is formed by growing on the first substrate 10. The piezoelectric layer 20 may be a single crystal piezoelectric layer 20, and a resonator made from this may have better performance. A material of the single crystal piezoelectric layer 20 may be AlN, ScAlN, YAlN, PZT, LiNbO₃, LiTaO₃, or the like. Then, a metal is deposited on the piezoelectric layer and is patterned to form a bottom electrode 30. A material of the bottom electrode 30 may be made of Mo, Al, Pt, Au, or the like.

As shown in FIG. 3, a mass loading layer is deposited on the bottom electrode 30 and is etched to form a first mass loading layer 40. By controlling a ratio of an area of the first mass loading layer to the effective working region of the resonator, a frequency required by the resonator is correspondingly achieved. Therefore, on the same wafer, multiple resonators with different resonant frequencies can be prepared by controlling the ratio of the area of the first mass loading layer 40 to the effective working region of the resonator to be different. A material of the first mass loading layer may be Al2O3, Mo, or the like.

As shown in FIG. 4, the device wafer also includes a sacrificial layer 50. The sacrificial layer 50 is formed by depositing a layer of sacrificial material on the bottom electrode 30, and then patterning the layer. The sacrificial layer 50 completely covers the first mass loading layer 40, thereby obtaining the device wafer as shown in FIG. 4. A material of the sacrificial layer 50 may be SiO2, PSG, BPSG, or the like.

As shown in FIG. 5, a supporting layer 60 is deposited on one side of the device wafer with the sacrificial layer 50. The supporting layer 60 may be AlN, Si, Al₂O₃, SiC, or the like.

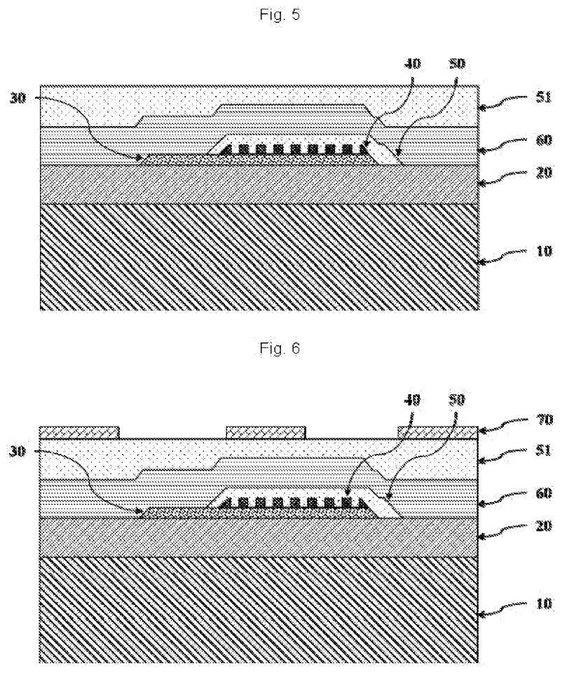

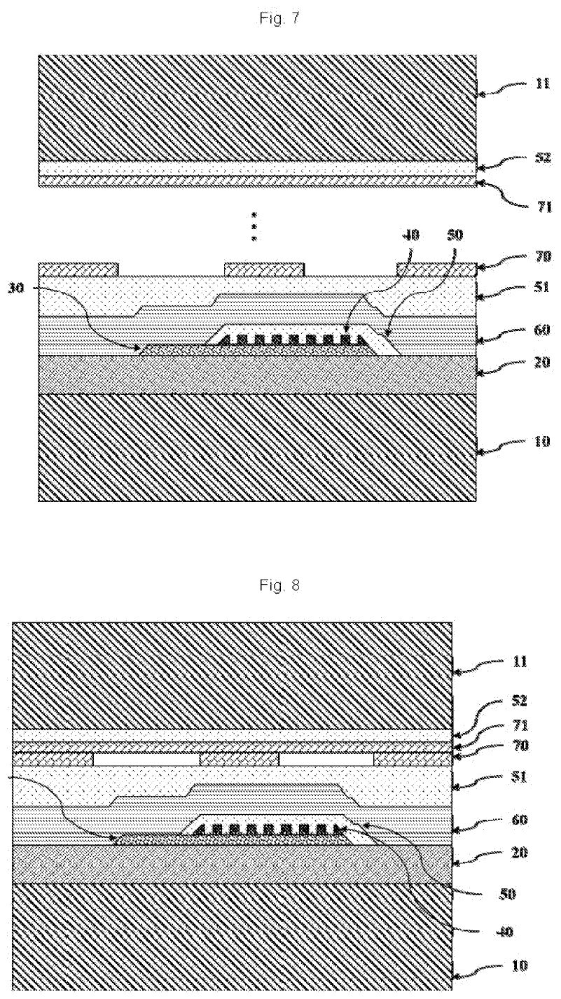

As shown in FIGS. 5 to 7 or FIGS. 14 and 15, a first transition layer is further deposited on the supporting layer 60 for bonding. Similarly, a second transition layer is deposited on a second substrate 11 for bonding.

As shown in FIGS. 7 to 8 or FIGS. 14 to 15, the second substrate 11 is formed on the supporting layer 60 by bonding the first transition layer with the second transition layer.

Specifically, according to a requirement, in one implementation, as shown in FIGS. 5 to 8, the first transition layer includes a first buffer layer 51 and a first bonding layer 70. The first buffer layer 51 is deposited on the supporting layer 60, and then a side surface of the first buffer layer 51 facing away from the supporting layer 60 is flattened (for example, by physical or chemical mechanical polishing (CMP)) to obtain a relatively flat surface for subsequent bonding. Then the first bonding layer 70 is deposited on the first buffer layer 51 and is etched, thereby reserving a bonding layer area in a certain proportion. Similarly, as shown in FIGS. 7 and 8, the second transition layer includes a second buffer layer 52 and a second bonding layer 71. The second buffer layer 52 is deposited on a surface of the second substrate 11, and the second bonding layer 71 is further deposited. The second substrate 11 is arranged on the device wafer by bonding the first bonding layer 70 with the second bonding layer 71. A material of the first buffer layer 51 and the second buffer layer 52 may be SiO2, and a material of the first bonding layer 70 and the second bonding layer 71 may be Au.

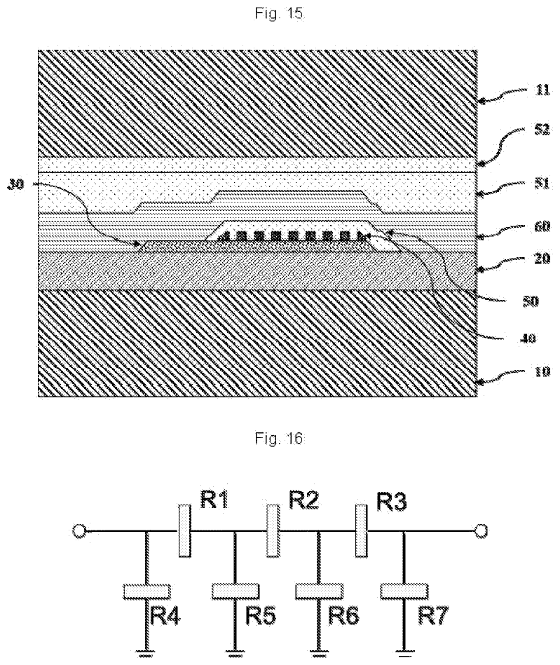

Specifically, according to a requirement, in another implementation, as shown in FIGS. 14 to 15, the first transition layer includes a first buffer layer 51. The first buffer layer 51 is deposited on the supporting layer 60, and then a side surface of the first buffer layer 51 facing away from the supporting layer 60 is flattened (for example, by physical or chemical mechanical polishing (CMP)) to obtain a relatively flat surface for subsequent bonding. Similarly, as shown in FIGS. 14 to 15, the second transition layer includes a second buffer layer 52. The second buffer layer 52 is deposited on a surface of the second substrate 11. The second substrate 11 is arranged on the device wafer by directly bonding the first buffer layer 51 with the second buffer layer 52. A material of the first buffer layer 51 and the second buffer layer 52 may be SiO2.

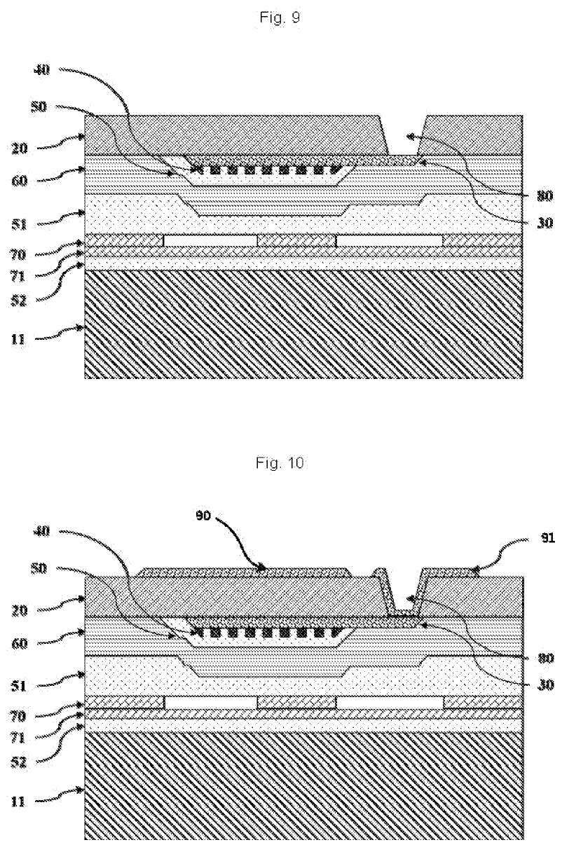

As shown in FIG. 9, a device is flipped, the first substrate 10 is removed by thinning plus dry etching or thinning plus wet etching, thereby exposing the side surface of the piezoelectric layer 20 facing away from the bottom electrode 30. By etching the piezoelectric layer 20, an electrode outlet hole 80 extending to the bottom electrode 30 is formed on the piezoelectric layer 20, and a portion of the bottom electrode 30 is exposed within the electrode outlet hole 80.

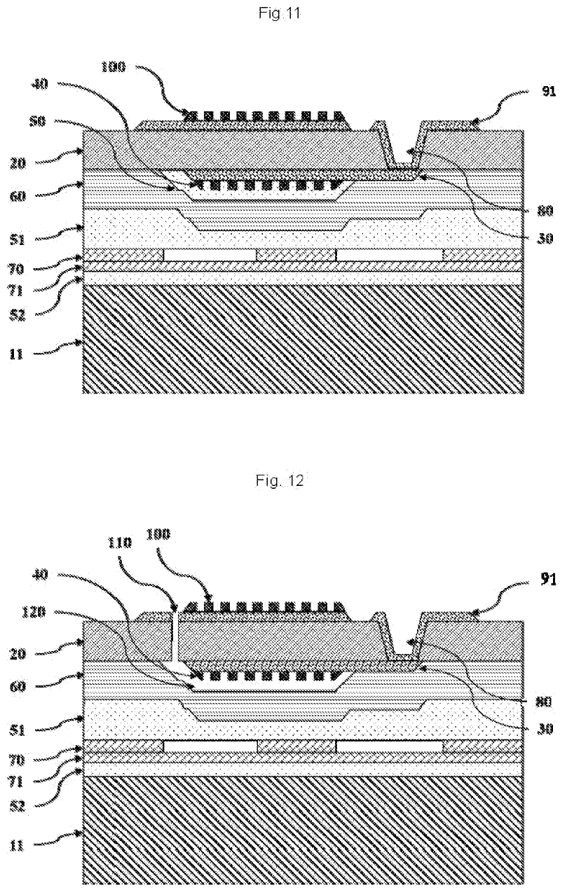

As shown in FIG. 10, a metal is deposited on a surface of the piezoelectric layer 20 with the electrode outlet hole 80, and two separated portions are formed through patterning. One portion serves as a top electrode 90, while the other portion is located inside the electrode outlet hole 80 and around a circumferential edge of the electrode outlet hole 80 as an extraction electrode 91. The extraction electrode 91 is connected to the bottom electrode 30 through the electrode outlet hole 80, thereby leading the bottom electrode 30 to an upper surface of the piezoelectric layer 20 for subsequent packaging and external connection. It should be noted that orthogonal projections of the top electrode 90 and the bottom electrode 30 on the piezoelectric layer 20 each have an overlapping region and a non-overlapping region, and the overlapping regions of the two projections serve as the effective working region of the resonator. The top electrode 90 includes two portions: One portion is located in the overlapping region, and the other portion is located in the non-overlapping region. The bottom electrode 30 also includes two portions: One portion is located in the overlapping region, and the other portion is located in the non-overlapping region. An arrangement position of the electrode outlet hole 80 is in the non-overlapping region of the bottom electrode 30 to avoid contact between the bottom electrode 30 and the top electrode 90.

As shown in FIG. 11, a mass loading layer is deposited on the top electrode 90 and is etched to form a second mass loading layer 100. By controlling an area ratio of the second mass loading layer 100 to the effective working region of the resonator, a frequency required by the resonator is correspondingly achieved.

As shown in FIG. 12, a through hole 110 penetrating through the sacrificial layer 50 is formed in a side surface of the top electrode 90 facing away from the bottom electrode 30. The sacrificial layer is released through the through hole 110 to form a cavity 120 between the first mass loading layer 40 and the supporting layer 60. It should be understood that the first mass loading layer 40, the second mass loading layer 100, and the cavity 120 are all located in the effective working region of the resonator.

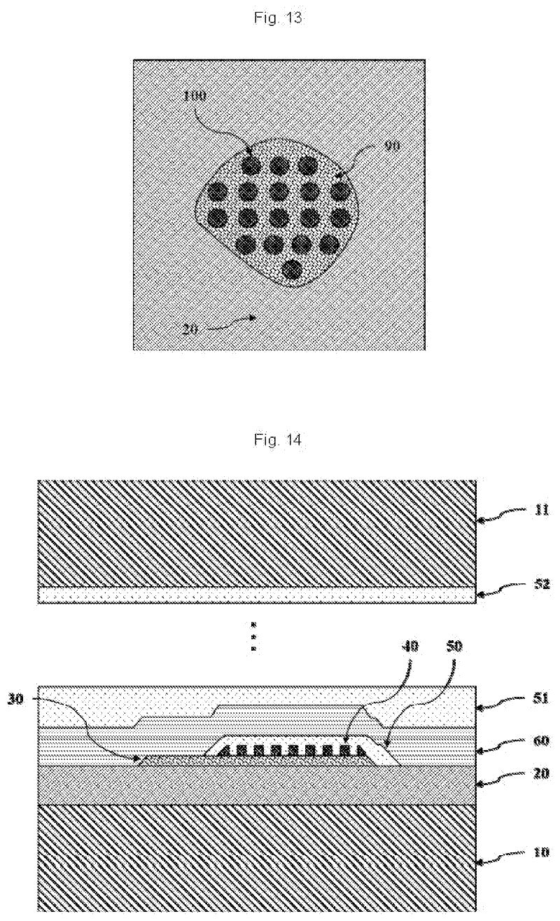

FIG. 13 shows the second mass loading layer 100 formed by etching. The second mass loading layer 100 includes a plurality of spaced mass blocks on the same layer. The mass blocks may be regular (for example, cylindrical or prismastic) or irregular block structures. The present application does not limit this. A cross section of the first mass block has the same shape as or different shape from the shape of a cross section of a second mass block. The cross sections of any two first mass blocks in the first mass loading layer 40 may be the same or different, and the cross sections of any two mass blocks in the second mass loading layer 100 may be the same or different. The present application also does not limit this, as long as a ratio of an area of the second mass loading layer 100 to the effective working region of the resonator satisfies a preset area ratio. It is not necessary to regularly periodically arrange regions left by the second mass loading layer after etching, but these regions may be arranged at intervals or irregularly, as long as they meet a required etching area. The ratios of the areas during etching of the first mass loading layer and the second mass loading layer or the regions left after etching (the first mass loading layer and the second mass loading layer are formed by patterning) do not need to be consistent. The same is to the first mass loading layer 40, which will not be repeated here. The invention point of the embodiments of the present application is to correspondingly tuning the resonator by controlling the ratio of the area of the first mass loading layer in the effective working region of the resonator to the area of the second mass loading layer in the effective working region of the resonator. The areas of the first mass loading layer and the second mass loading layer in the effective working region of the resonator may be set according to an actual requirement.

According to another aspect of the embodiments of the present application, a resonator is provided, as shown in FIG. 12, including a second substrate 11 and a supporting layer 60 arranged on the second substrate 11. A bottom electrode 30, a piezoelectric layer 20, and a top electrode 90 are arranged on the supporting layer 60 in sequence, and a cavity 120 is formed between the bottom electrode 30 and the supporting layer 60. A first mass loading layer 40 is formed on a side surface of the bottom electrode 30 close to the cavity 120, and a second mass loading layer 100 is formed on a side surface of the top electrode 90 facing away from the cavity 120. The first mass loading layer 40, the second mass loading layer 100, and the cavity 120 are all located in an effective working region of the resonator. In this embodiment, thicknesses of the various layers of the resonator remain unchanged, an area of the first mass loading layer in the effective region of the resonator is controlled to remain unchanged, and an area of the second mass loading layer in the effective region of the resonator is changed, thereby changing a ratio of the areas of the first mass loading layer and the second mass loading layer to the effective region of the resonator, and achieving frequency adjustment. Specific implementations are provided below.

As shown in FIG. 17, the bottom electrode 30 is provided with a first mass loading layer 40. A plurality of first mass blocks are arranged on the first mass loading layer 40, and are dispersed on the bottom electrode 30. A shape of a cross section of each first mass block is a closed pattern composed of a circle, or a trapezoid, or a triangle, or an arc, and distances between centers of two adjacent first mass blocks are equal.

As shown in FIG. 18, the top electrode 90 is provided with a second mass loading layer 100. A plurality of second mass blocks are arranged on the second mass loading layer 100, and are dispersed on the top electrode 90. A shape of a cross section of each second mass block is a closed pattern composed of a circle, or a trapezoid, or a triangle, or an arc, and distances between centers of two adjacent second mass blocks are equal. A first total projection area of all the first mass blocks on the first mass loading layer 40 in the effective working region of the resonator is obtained; a second total projection area of all the second mass blocks on the second mass loading layer 100 in the effective working region of the resonator is obtained; and a frequency of the resonator is adjusted by controlling a ratio of the first total projection area to the second total projection area. In this embodiment, at this time, the ratio of the area of the first mass loading layer in the effective working region of the resonator to the area of the second mass loading layer 100 in the effective working region of the resonator is 1:1.

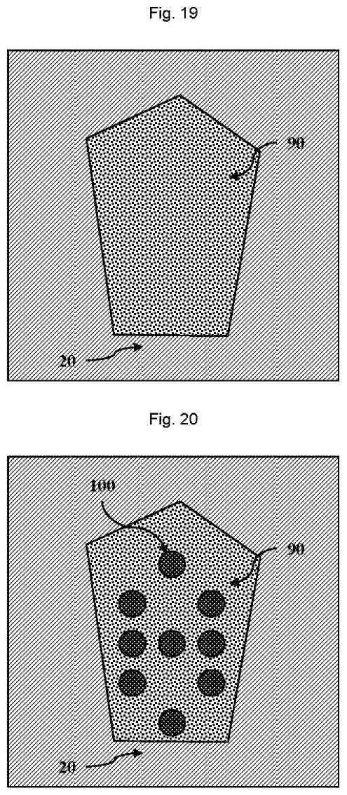

As shown in FIG. 19, there is no second mass loading layer 100 arranged on the top electrode so that at this time, the ratio of the first total projection area to the second total projection area is 1:0.

As shown in FIG. 20, mass loading layers with different areas are arranged on the top electrode so that at this time, the ratio of the first total projection area to the second total projection area is 1:0.5625.

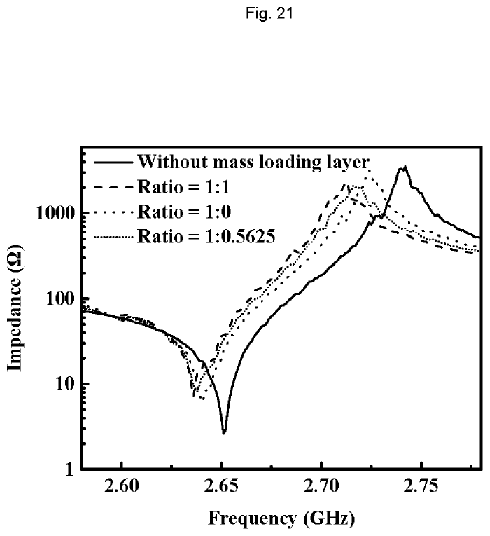

In the above three cases, the ratios of the areas of the first mass loading layer 40 in the effective region of the resonator to the areas of the second mass loading layer 100 in the effective region of the resonator are different. FIG. 21 shows changes of a response curve of the resonator after software simulation is performed in the three cases. Meanwhile, it can be seen by comparison with a case where the top and bottom electrodes are neither provided with mass loading layers that the series resonant frequency and the parallel resonance frequency significantly change.

Similarly, the top electrode 90 is provided with mass loading layers with different areas, and the ratio of the first total projection area to the second total projection area is set to 1:1.5 to achieve adjustment of different frequencies.

As shown in Table 1, the resonant frequencies of the resonators obtained by simulation in cases where the ratio of the area of the first mass loading layer 40 in the effective region of the resonator to the area of the second mass loading layer 100 in the effective region of the resonator is different correspond to FIG. 21.

Table 1 further shows that the resonant frequencies of the resonators obtained by simulation in cases where the ratio of the area of the first mass loading layer 40 in the effective region of the resonator to the area of the second mass loading layer 100 in the effective region of the resonator is different all change.

TABLE 1

| | With no mass | | | Ratio = |
|---|---|---|---|---|
| | loading layer | Ratio = 1:1 | Ratio = 1:0 | 1:0.5625 |
| Series | 2.651 | 2.636 | 2.640 | 2.638 |
| resonant | | | | |
| frequency | | | | |
| (GHz) | | | | |
| Parallel | 2.742 | 2.712 | 2.724 | 2.716 |
| resonant | | | | |
| frequency | | | | |
| (GHz) | | | | |

In the present application, the resonator is correspondingly tuned by controlling a ratio of an area of the first mass loading layer 40 in an effective working region of the resonator to an area of the second mass loading layer 100 in the effective working region of the resonator, so that the ratios of the areas of the mass loading layers of various resonators in the effective working regions can be controlled to be different on the same wafer, thereby manufacturing resonators with different resonant frequencies, effectively avoiding loss caused by tuning with an external element, and ensuring good performance of the resonator.

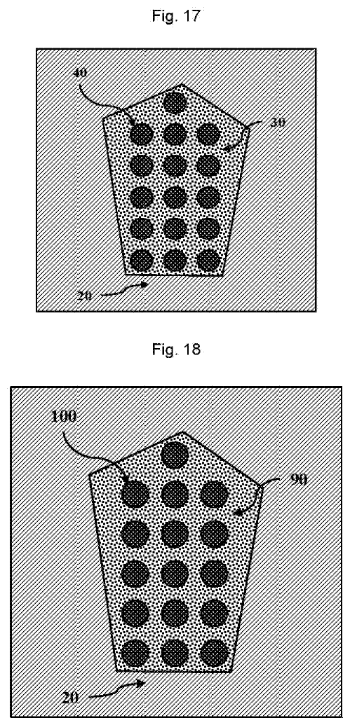

According to still another aspect of the embodiments of the present application, a filter is provided, including any one of the above resonators. FIG. 16 shows a schematic structural diagram of a filter, including a first resonator R1, a second resonator R2, a third resonator R3, a fourth resonator R4, a fifth resonator R5, a sixth resonator R6, and a seventh resonator R7. The first resonator R1, the second resonator R2, and the third resonator R3 are series resonators, and the fourth resonator R4, the fifth resonator R5, the sixth resonator R6, and the seventh resonator R7 are parallel resonators. At least one of the first resonator R1, the second resonator R2, the third resonator R3, the fourth resonator R4, the fifth resonator R5, the sixth resonator R6, and the seventh resonator R7 mentioned above serves as the above resonator.

The above descriptions are merely preferred embodiments of this application and are not intended to limit this application. For those skilled in the art, this application may have various modifications and changes. Any modification, equivalent replacement, or improvement made without departing from the spirit and principle of the present application shall fall within the protection scope of the present application.

What is claimed is:

1. A method of preparing a resonator, the method comprising:
providing a device wafer, wherein the device wafer comprises a first substrate and a piezoelectric layer, a bottom electrode, and a first mass loading layer formed in sequence on the first substrate, and
the device wafer further comprises a sacrificial layer formed on the bottom layer and covering the first mass loading layer;
forming a supporting layer on one side of the device wafer with the sacrificial layer;
forming a second substrate on the supporting layer through a bonding process;
removing the first substrate to expose the piezoelectric layer;
forming a top electrode and a second mass loading layer in sequence on the piezoelectric layer; and
releasing the sacrificial layer to form a cavity between the first mass loading layer and the supporting layer, wherein the first mass loading layer, the second mass loading layer, and the cavity are all located in an effective working region of the resonator.

2. The method of preparing the resonator according to claim 1, wherein the first mass loading layer comprise a plurality of mass blocks distributed on a same layer, and/or the second mass loading layer comprise a plurality of mass blocks distributed on a same layer.

3. The method of preparing the resonator according to claim 1, wherein the forming the second substrate on the supporting layer through a bonding process comprises:
forming a first transition layer on the supporting layer;
forming a second transition layer on the second substrate; and
bonding the first transition layer with the second transition layer to form the second substrate on the supporting layer.

4. The method of preparing the resonator according to claim 3, wherein the first transition layer comprises a first buffer layer formed on the supporting layer and a first bonding layer formed on the first buffer layer; and the second transition layer comprises a second buffer layer formed on the second substrate and a second bonding layer formed on the second buffer layer.

5. The method of preparing the resonator according to claim 3, wherein the first transition layer comprises a first buffer layer formed on the supporting layer; and the second transition layer comprises a second buffer layer formed on the second substrate.

6. The method of preparing the resonator according to claim 4, wherein after forming a first buffer layer on the supporting layer, the method further comprises:
flattening the first buffer layer.

7. The method of preparing the resonator according to claim 1, wherein the releasing the sacrificial layer to form a cavity between the first mass loading layer and the supporting layer comprises:
etching one side surface of the top electrode facing away from the bottom electrode to form a through hole penetrating through the sacrificial layer; and
releasing the sacrificial layer through the through hole to form the cavity between the first mass loading layer and the supporting layer.

8. The method according to claim 1, wherein a plurality of first mass blocks are arranged on the first mass loading layer, and are dispersed on the bottom electrode, and wherein a plurality of second mass blocks are arranged on the second mass loading layer, and the second mass blocks are dispersed on the top electrode, the method further comprises:
Obtaining a first total projection area of the first mass blocks in the effective working region of the resonator; and a second total projection area of the second mass blocks in the effective working region of the resonator;
Adjusting a frequency of the resonator by controlling a ratio of the first total projection area to the second total projection area.

9. The method according to claim 8, wherein the ratio of the first total projection area to the second total projection area is 1:1.

10. The method according to claim 8, wherein the ratio of the first total projection area to the second total projection area is 1:0.

11. The method according to claim 8, wherein the ratio of the first total projection area to the second total projection area is 1:0.5625.

12. The method according to claim 8, wherein the ratio of the first total projection area to the second total projection area is 1:1.5.

13. A resonator, comprising a second substrate and a supporting layer arranged on the second substrate, wherein a bottom electrode, a piezoelectric layer, and a top electrode are arranged on the supporting layer in sequence, and a cavity is formed between the bottom electrode and the supporting layer; a first mass loading layer is formed on a side surface of the bottom electrode close to the cavity, and a second mass loading layer is formed on a side surface of the top electrode facing away from the cavity; and the first mass loading layer, the second mass loading layer, and the cavity are all located in an effective working region of the resonator.

14. The resonator according to claim 13, wherein the first mass loading layer comprise a plurality of mass blocks distributed on a same layer, and/or the second mass loading layer comprise a plurality of mass blocks distributed on a same layer.

15. The resonator according to claim 13, wherein a first transition layer and a second transition layer bonded with each other are further arranged between the second substrate and the supporting layer.

16. The resonator according to claim 15, wherein a plurality of first mass blocks are arranged on the first mass loading layer, and are dispersed on the bottom electrode.

17. The resonator according to claim 16, wherein a shape of a cross section of each first mass block is a closed pattern composed of a circle, or a trapezoid, or a triangle, or an arc, and distances between centers of two adjacent first mass blocks are equal.

18. The resonator according to claim 17, wherein a plurality of second mass blocks are arranged on the second mass loading layer, and the second mass blocks are dispersed on the top electrode.

19. The resonator according to claim 18, wherein a shape of a cross section of each second mass block is a closed pattern composed of a circle, or a trapezoid, or a triangle, or an arc, and distances between centers of two adjacent second mass blocks are equal.

20. The resonator according to claim 18, wherein a cross section of the first mass block has the same shape as the shape of a cross section of the second mass block.
